(19) United States
(12) Patent Application Publication
(10) Pub. No.: US 2011/0147759 A1
(43) Pub. Date: Jun. 23, 2011

(54) GROUP III NITRIDE SEMICONDUCTOR SUBSTRATE AND MANUFACTURING METHOD OF THE SAME

(75) Inventor: Yuichi OSHIMA, Tsuchiura-shi (JP)

(73) Assignee: HITACHI CABLE, LTD., Tokyo (JP)

(21) Appl. No.: 12/789,746

(22) Filed: May 28, 2010

(30) Foreign Application Priority Data
Dec. 18, 2009 (JP) 2009-287528

(51) Int. Cl. H01L 29/20; H01L 21/20

(52) U.S. Cl. 257/76; 257/615; 438/478; 257/E29.089; 257/E21.461

(57) ABSTRACT

A Group III nitride semiconductor substrate is provided, with diameter of 25 mm or more and thickness of 250 μm or more, wherein in at least an outer edge side part of an outer edge part within 5 mm from an outer edge of the group III nitride semiconductor substrate, stress within a main surface of the group III nitride semiconductor substrate works as a tensile stress, with the tensile stress becoming relatively greater compared to that of a center side part from the outer edge side part of the group III nitride semiconductor substrate.

### BACKGROUND

1. Technical Field

The present invention relates to a group III nitride semiconductor substrate and a manufacturing method of the same, and particularly relates to the group III nitride semiconductor substrate improved in cleavage characteristics and the manufacturing method of the same.

2. Description of Related Art

Group III nitride semiconductors such as gallium nitride (GaN), indium gallium nitride (InGaN), and aluminium gallium nitride (AlGaN) attract attention as materials of light emitting diodes (LEDs) of blue color and laser diodes (LDs) of blue color. Further, by taking advantage of the characteristics of the group III nitride semiconductor such as having excellent heat resistance property and environmental resistance property, development of application to electronic devices has been started.

A substrate for GaN growth in wide practical use at present is sapphire, and a method of epitaxially-growing GaN by metal-organic vapor phase epitaxy (MOVPE) on a single crystal sapphire substrate is generally used. GaN will be explained hereafter, as a typical example of the Group III nitride semiconductor.

A lattice constant of sapphire is different from that of GaN, and therefore a single crystal film can not be grown only by directly growing GaN on the sapphire substrate. Therefore, a method is considered as follows: a nitride buffer layer of AlN or GaN is grown on the sapphire substrate at a lower temperature once, a strain of a lattice is alleviated, and GaN is grown thereon. By using a low temperature growing nitride layer as a buffer layer, single crystal epitaxial growth of GaN is achieved. However, even in this method, difference of the lattice constant between the sapphire and the GaN crystal is still greatly problematic, and the grown GaN has ultra-high density of crystal defects. Such crystal defects are sometimes a barrier in manufacturing GaN-based LDs and high luminance LEDs.

From the reason as described above, an emergence of a free-standing GaN substrate has been ardently desired. In a case of GaN, it is difficult to grow a large sized ingot from melt like Si and GaAs. Therefore, various methods such as high temperature/high pressure method, Na flux method, and Hydride Vapor Phase Epitaxy (HVPE) have been tried. Among them, development of the GaN substrate by HVPE has been progressed most. Distribution to market is started, and there are great expectations to develop the GaN substrate not only as LDs but also as high luminance LEDs.

Normally, an end face mirror of a resonator of LD is formed by cleavage. Conventionally disclosed method is as follows: monochromatic light is applied to an entire surface of a single crystal GaN substrate, to measure strain values by photoelastic effect, and a cleavage property of the single crystal GaN substrate is judged, depending on whether a maximum value in the GaN substrate surface of the measured distortional value falls within a prescribed value (see patent document 1)

### (Patent Document 1)

Japanese Patent Laid Open Publication No. 2002-299741

As described above, although the GaN substrate by HVPE is put into practical use, characteristics of the GaN substrate leave much for improvement. A problem to be solved here is the cleavage property of the GaN substrate. Normally, an end face mirror of a resonator of LD is formed by cleavage. Principally, a cleavage plane has flatness at an atomic level, and is supposed to be ideal as a mirror. However, in an actual cleavage plane, disturbance of flatness such as a macro-step (difference-in-level) is generated due to various factors, thus causing decrease in yield rate of LDs. FIG. 5 shows a differential interference contrast image obtained by observing the cleavage plane formed by cleaving a conventional GaN substrate manufactured by HVPE, using a differential interference microscope (“BX11” by OLYMPUS Corporation). The macro-step is observed in the cleavage plane of a part surrounded by broken line in FIG. 5.

### SUMMARY OF THE INVENTION

An object of the present invention is to provide the group III nitride semiconductor substrate capable of obtaining a flat cleavage plane with little disturbance of flatness such as a macro-step, and a manufacturing method of the same.

An aspect of the present invention is to provide a group III nitride semiconductor substrate with diameter of 25 mm or more and thickness of 250 μm or more, wherein in at least an outer edge side part of an outer edge part within 5 mm from an outer edge of the group III nitride semiconductor substrate, stress within a main surface of the group III nitride semiconductor substrate works as a tensile stress, with the tensile stress becoming relatively greater compared to that of a center side part from the outer edge side part of the group III nitride semiconductor substrate.

Other aspect of the present invention is to provide a manufacturing method of a group III nitride semiconductor substrate, comprising the steps of:

preparing a seed crystal substrate; and

supplying a raw material to the seed crystal substrate and crystal-growing thereon a group III nitride semiconductor layer,

wherein in the step of crystal-growing the group III nitride semiconductor layer on the seed crystal substrate, the group III nitride semiconductor layer crystal-grows on an outer peripheral part thereof while growth planes are formed so as to be inclined to a main surface of the seed crystal substrate at an angle larger than 0° and smaller than 90°, with a doping concentration of the group III nitride semiconductor layer of the outer peripheral part having the inclined growth planes, set to be higher than the doping concentration of the group III nitride semiconductor layer of a center side from the outer peripheral part.

### BRIEF DESCRIPTION OF THE DRAWINGS

FIG. 1A to FIG. 1F are step views showing the steps of a manufacturing method of a group III nitride semiconductor substrate according to an example of the present invention, respectively.

FIG. 2 is a graph showing a correlation between an outer peripheral tensile stress of a substrate outer peripheral part, and an oxygen concentration of an inclined growth part.

FIG. 3 is a graph showing a relation between the outer peripheral tensile stress of the substrate outer peripheral part, density of macro-steps in a cleavage plane, and a crack generation rate.

FIG. 4 is a graph showing a relation between the outer peripheral tensile stress of the substrate outer peripheral part, and yield rate of LDs.

FIG. 5 shows a differential interference contrast image showing a macro-step in the cleavage plane observed by a differential interference microscope.

FIG. 6A to FIG. 6C show details of a GaN layer in as-grown state obtained by the crystal growing step of the group III nitride semiconductor layer according to an example of the present invention, wherein FIG. 6A is a plan view, FIG. 6B is a side view, and FIG. 6C is an expanded sectional view of apart (conical surface part) of an inclined surface of the GaN layer.

### DESCRIPTION OF PREFERRED EMBODIMENT OF THE INVENTION

Prior to explanation for an embodiment of a group III nitride semiconductor substrate and a manufacturing method of the same according to the present invention, explanation will be given for main factors considered to cause the macro-steps to be generated in the cleavage plane during cleavage processing of a substrate of the group III nitride semiconductor such as GaN, as listed below.

### (a) Imperfection of the Cleavage Property, Due to a Crystal Structure

A stable crystal structure of the group III nitride semiconductor including GaN is a hexagonal crystal, and the cleavage property of the hexagonal crystal is not so distinct as the cleavage property of a cubic crystal. Therefore, originally, the group III nitride semiconductor easily allows the macro-steps in the cleavage plane to be generated.

### (b) Local Variation of Internal Stress

Crystals of the group III nitride semiconductor including GaN are manufactured in most cases by heteroepitaxial growth, with a heterogeneous substrate (foreign substrate) such as sapphire or GaAs as a base. This is a heteroepitaxial growth with large lattice mismatching, and therefore a high density crystal defect (dislocation) occurs in an interface between an epitaxial layer and the substrate. In order to reduce a dislocation density, for example, a technique of forming a mask having an opening part on a base substrate, and making GaN layer grow laterally from the opening part to obtain the GaN layer with less dislocation, or a so-called ELO (Epitaxial Lateral Overgrowth) technique, is often used. However, although reduction of the dislocation density is achieved, a low dislocation density region and a high dislocation density region are formed, to generate nonuniformity in the dislocation density in some cases. It can be considered that the nonuniformity of the dislocation density causes a local variation of the internal stress to occur through a stress field of the dislocation, and as a result, causes the macro-steps in the cleavage plane. The local variation of the internal stress can be generated not only in a substrate in-plane direction, but also in a substrate thickness direction.

### (c) Mode of Force Application

In a general method of applying cleavage to the GaN substrate, first, small and sharp cut along a cleavage direction is added to an edge part of the substrate. At this time, a so-called diamond pen or a scriber is used. Thereafter, when a force for widening the cut of the edge part of the substrate is added, crack extends to an opposite side of the substrate, with the cut of the end part as a starting point, to thereby complete the cleavage of the substrate. At this time, if the force is not added with appropriate direction and strength, the macro-steps are easily generated particularly near the cut added to the edge part.

The following countermeasure can be considered, to reduce each factor of causing problems as described above.
(i) The substrate is made thin by lapping the substrate from a rear surface side before adding cleavage thereto. The macro-steps in the cleavage plane are extremely reduced by making the substrate thin, which is processed to have a thickness of 200 μm or less. As one of the factors, it can be considered that a stress variation in the substrate thickness direction becomes small by making the substrate thin.
(ii) It is effective to use a homogeneous substrate without nonuniformity in the dislocation density. In manufacturing the substrate with uniform dislocation density, for example, VAS method (Void-Assisted Separation Method) can be suitably used, comprising the steps of: vapor-depositing Ti on the surface of the GaN thin film on a sapphire substrate; forming a void structure in the GaN thin film by applying heat treatment thereto; making GaN grown thick thereon by HVPE method; and separating the sapphire substrate from the void structure part.

However, even after such a countermeasure is taken, the macro-steps in the cleavage plane near the edge part of the substrate are still in a state of being easily generated, due to the factor (C).

An inventor of the present invention considers as follows: namely, the cleavage plane is disturbed by factor (C), and this is because a great force is required to be added during cleavage from the edge part of the substrate, because of an indistinct cleavage property originally provided in the Group III nitride semiconductor crystal described in the factor (a), and when the cleavage is carried out by adding a great force, the macro-steps are easily generated depending on the direction or strength of the added force, and if the cleavage is achieved with a lighter force, this problem can be solved.

It can be easily estimated that by making the substrate thinner, magnitude of an external force required for the cleavage can be made small. However, there is a risk of damaging the substrate during handling, and therefore practically, around 200 μm of status quo is considered to be a limit, and in a method of making the substrate thin, further improvement of the cleavage property is impossible.

Therefore, as a result of strenuous examination by the inventor of the present invention, it is found that the tensile stress is internally provided to the outer edge part of the substrate, being a starting point of the cleavage. This is an idea as follows: when the tensile stress of the substrate is internally provided to the outer edge part of the substrate, the cleavage is spontaneously started only by adding a light force, and therefore, the generation of the macro-steps in the cleavage plane is inhibited, compared with a case that an unreasonable force is added.

As a specific method for providing the tensile stress to the outer edge part of the substrate, the inventor of the present invention found a method of carrying out the crystal growth on the outer peripheral part of the substrate, while forming a region where the doping concentration is high. Namely, the region where the doping concentration is high, is formed on the outer peripheral part of a growth region, and the tensile stress is generated by mismatching due to doping in terms of physical properties. However, the width of the region having the tensile stress is preferably set within 5 mm from the outer edge of the substrate having diameter of, for example, 25 mm or more. If the width of the region of the tensile stress is wider than 5 mm, there is a risk that an overall substrate is warped. Further, even in a case of a narrow width of the region of the tensile stress, steep variation of the stress is required at a boundary between the region having the tensile stress of the outer edge part of the substrate and the region of the substrate center side. However, normally, in a growth process of the crystal, it is difficult to supply dopant raw materials by limiting only in a narrow region without diffusing the materials.

Therefore, the inventor of the present invention devises a method of utilizing a difference of incorporation efficiency of the dopant depending on crystal plane indices. For example, even under the same growth condition, GaN grown on (10-11) plane or (11-22) plane incorporates almost 1000-fold more oxygen than the GaN which is grown on (0001) plane (c-plane) in some cases. Namely, an inclined facets (such as planes formed of (10-11) plane or (11-22) plane, etc.) is formed on the outer peripheral part of the crystal intended to be grown, for example with c-plane as a main surface, and the crystal growth is carried out while supplying oxygen or oxygen compound into the atmosphere. Thus, two different regions can be formed across a steep interface, such as a region where the oxygen doping concentration of the outer peripheral part growing with the inclined facets is high, and a region where the oxygen doping concentration of a center side part growing with c-plane is low.

However, an excessive tensile stress causes unintended cracks to occur to the substrate in some trivial chance, during handling and carrying out epitaxial growth. In a case of an excessively small tensile stress as well, an effect of improving the cleavage property is not exhibited. Therefore, the tensile stress needs to be adjusted within a proper range. The tensile stress can be adjusted by adjusting a difference in doping concentration between the outer peripheral part and the center part side of the substrate, and also can be adjusted by decreasing the width of a tensile stress generation part by applying grinding processing to the outer peripheral part of the substrate.

An embodiment of the group III nitride semiconductor substrate and the manufacturing method of the same according to the present invention will be described hereafter.

A group III nitride semiconductor substrate according to this embodiment is the group III nitride semiconductor substrate with diameter of 25 mm or more and thickness of 250 μm or more, wherein in at least the outer edge side part of an outer edge part within 5 mm from an outer edge of the group III nitride semiconductor substrate, stress within a main surface of the group III nitride semiconductor substrate works as a tensile stress, with the tensile stress becoming relatively greater compared to that of a center side part from the outer edge side part of the group III nitride semiconductor substrate.

By providing a part having the tensile stress to the outer edge part within 5 mm from the outer edge of the group III nitride semiconductor substrate, spontaneous propagation of cracks during cleavage can be promoted, and the generation of the macro-steps in the cleavage plane can be inhibited.

Preferably magnitude of the tensile stress possessed by the outer edge part of the substrate is set to 30 MPa or more and 150 MPa or less. This is because when the tensile stress is set to 30 MPa or more, the generation of the macro-steps in the cleavage plane can be effectively inhibited, and when the tensile stress exceeds 150 MPa, frequency of breakages of the substrates into irregular shapes during handling is increased. The magnitude of further preferable tensile stress is 50 MPa or more and 120 MPa or less.

The stress (stress distribution) in the main surface of the group III nitride semiconductor substrate can be obtained, for example, by photoelastic measurement. Here, the photoelastic measurement is a method of measuring a deviation amount of phases of light transmitted through a sample, which is caused by birefringence, thereby making it possible to measure the stress of the sample, because the deviation amount of the phases and the stress of the sample have a correlation with each other.

The tensile stress of the outer edge part of the substrate is relatively greater than that of the center side part, and this case includes a case that the center side part of the substrate has a smaller tensile stress than the tensile stress of the outer edge part, and a case that the center side part of the substrate has a zero force, or the center side part of the substrate has a compressive stress.

Further, the main surface of the group III nitride semiconductor substrate is preferably formed into the c-plane or an inclined plane inclined from the c-plane. This is because when the main surface of the group III nitride semiconductor substrate is the c-plane or the inclined plane close to the c-plane, it is suitable to make an element structure such as light emitting devices grow on the group III nitride semiconductor substrate (freestanding substrate). Note that the main surface of the group III nitride semiconductor substrate may be a-plane, m-plane, or an inclined plane inclined from the a-plane or m-plane, in addition to the c-plane or the inclined plane inclined from the c-plane. Wherein, the inclined plane inclined from the c-plane, etc, is preferably the plane inclined within an angle of 10° with respect to the c-plane, etc.

The group III nitride semiconductor substrate is preferably a freestanding substrate. The “freestanding substrate” means the substrate capable of holding its own shape and also having a strength not allowing inconvenience to be generated in handling. In order to have such strength, the thickness of the freestanding substrate is preferably set to 250 μm or more. Further, in consideration of facilitating the cleavage after an element is formed on the freestanding substrate, the thickness of the freestanding substrate is preferably set to 1 mm or less.

The group III nitride semiconductor substrate is preferably formed as the freestanding substrate having diameter of 25 mm or more. The diameter of the group III nitride semiconductor substrate depends on the diameter of the base substrate (seed crystal substrate) used in manufacturing, and by using the base substrate with a large diameter, the freestanding substrate with large diameter can also be obtained accordingly. For example, a sapphire substrate with diameter of 6 inches (152.4 mm) is commercially-supplied, and therefore by using this sapphire substrate, a GaN seed crystals substrate with diameter of 6 inches can be manufactured, and further by using the GaN seed crystal substrate, the GaN freestanding substrate with diameter of 6 inches or less can be manufactured.

Next, the manufacturing method of the group III nitride semiconductor substrate according to an embodiment of the present invention will be described.

The manufacturing method of a group III nitride semiconductor substrate includes the steps of:

preparing a seed crystal substrate; and

supplying a raw material to the seed crystal substrate and crystal-growing thereon a group III nitride semiconductor layer,

wherein in the step of crystal-growing the group III nitride semiconductor layer on the seed crystal substrate, the group III nitride semiconductor layer crystal-grows on an outer peripheral part thereof while growth planes are formed so as to be inclined to a main surface of the seed crystal substrate at an angle larger than 0° and smaller than 90°, with a doping concentration of the group III nitride semiconductor layer of the outer peripheral part having the inclined growth planes, set to be higher than the doping concentration of the group III nitride semiconductor layer of the center side from the outer peripheral part.

In order to carry out the crystal growth while inclined growth planes are formed on the outer peripheral part of the group III nitride semiconductor layer, for example, there is a method such that the outer peripheral part of the seed crystal substrate surface is covered with an annular mask, and when the crystal growth of the group III nitride semiconductor layer is carried out on the seed crystal substrate inside of the mask, the crystal growth is carried out based on a growth condition that inclined facets are formed on the outer peripheral part of the group III nitride semiconductor layer.

Planes easy to incorporate the dopant such as oxygen are selected as the inclined growth planes. For example, when GaN crystal is grown with c-plane as a main face, the crystal growth is carried out in such a manner that inclined facets formed of {10-11} planes equivalent to (10-11) plane, or {11-22} planes equivalent to (11-22) plane are formed on the outer peripheral part of the crystal.

The group III nitride semiconductor substrate such as a GaN substrate, the sapphire substrate, or the GaAs substrate is used as the seed crystal substrate (base substrate). Further, the GaN substrate, AlN substrate, AlGaN substrate, etc, can be given as the group III nitride semiconductor substrate manufactured from the Group III nitride semiconductor layer.

HVPE or MOVPE can be used as vapor phase epitaxy, for the crystal growth of the group III nitride semiconductor layer. However, particularly the HVPE is preferably used. For example, GaN growth is carried out as follows by using the HVPE. HCl gas is supplied to a vessel containing melt Ga, to thereby generate GaCl gas, and the GaCl gas and separately introduced NH₃ gas are supplied to the seed crystal substrate in a heating state in a growth furnace of the HVPE apparatus, then the GaCl and NH₃ are reacted on the surface of the seed crystal substrate, to thereby make GaN crystal grow thereon.

The crystal growth of the group III nitride semiconductor such as GaN is carried out in the growth furnace set in an atmosphere in which oxygen gas and oxygen compound gas exist, so that the group III nitride semiconductor crystal is doped with oxygen. The oxygen gas or the oxygen compound gas is supplied from outside of the growth furnace in which the crystal growth is carried out, or the oxygen, etc, generated by the reaction between a quartz member such as a reaction tube constituting the growth furnace and the atmosphere gas in the growth furnace, is supplied.

A detailed mechanism of generating the oxygen gas by the reaction between the quartz member such as the reaction tube constituting the growth furnace and the atmosphere gas in the growth furnace is not clarified. In the HVPE, which is a hot-wall system, the quartz reaction tube, etc, is heated by an external heater to a high temperature, and in the HVPE, a chloride raw material (such as HCl gas) is used. Therefore the chloride raw material and the quartz member are brought into contact with each other at a high temperature to decompose quartz, thus generating gas containing Si (silicon) or O (oxygen). Therefore, it can be considered that the GaN grown by the HVPE is easily doped with Si and O, compared with the MOVPE, being a cold wall system, not using the chloride raw material.

The amount of the oxygen gas generated by the reaction between the quartz member such as the reaction tube and the atmosphere gas in the growth furnace may be adjusted, for example as follows. When a surface area of the quartz member (installed in a high temperature region of the growth furnace) brought into contact with the source gas is increased, an oxygen amount is increased, and when the high temperature region of the growth furnace is made of, for example, graphite, the oxygen amount is decreased. Further, the amount of the oxygen gas can be adjusted even under the growth condition. When a growth rate and the growth temperature are increased, a large amount of oxygen is likely to be incorporated to the Group III nitride semiconductor crystal.

When the group III nitride semiconductor layer is doped with oxygen, the oxygen concentration in the group III nitride semiconductor layer of the outer peripheral part having inclined growth planes is preferably set to 1×10¹⁸ cm⁻³ or more and 5×10²⁰ cm⁻³ or less. By setting the oxygen concentration in this range, proper tensile stress capable of inhibiting the generation of the macro-steps during cleavage can be given to the outer edge part of the group III nitride semiconductor substrate. The oxygen concentration in the group III semiconductor layer of the center side part from the outer peripheral part is preferably set to not more than a lower limit value (2×10¹⁶ cm⁻³) of a general secondary ion mass spectrometer (SIMS).

After the step of crystal-growing the group III nitride semiconductor layer, the step of grinding the outer peripheral part of the group III nitride semiconductor layer may be performed. The tensile stress is provided or adjusted by making the group III nitride semiconductor substrate have a difference in doping concentration. However, by grinding the outer peripheral part of the group III nitride semiconductor substrate in addition to providing the difference in doping concentration, the width of the tensile stress part can be adjusted to be small.

Note that as shown in examples as will be described later, when oxygen with high concentration is added and the tensile stress is given to the outer peripheral part having the inclined growth planes, the tensile stress remains in the region of the group III nitride semiconductor layer with low oxygen concentration, at the center side from the outer peripheral side. Therefore, even when the outer peripheral part having the inclined growth planes is entirely removed by grinding processing, the III group nitride semiconductor substrate with excellent cleavage property can be obtained.

### EXAMPLES

Next, examples of the present invention will be described.

### Example 1

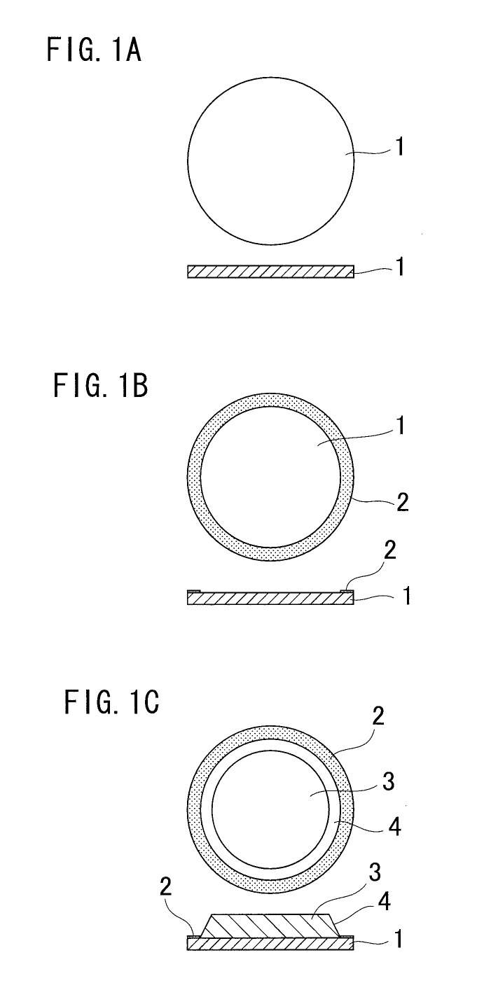

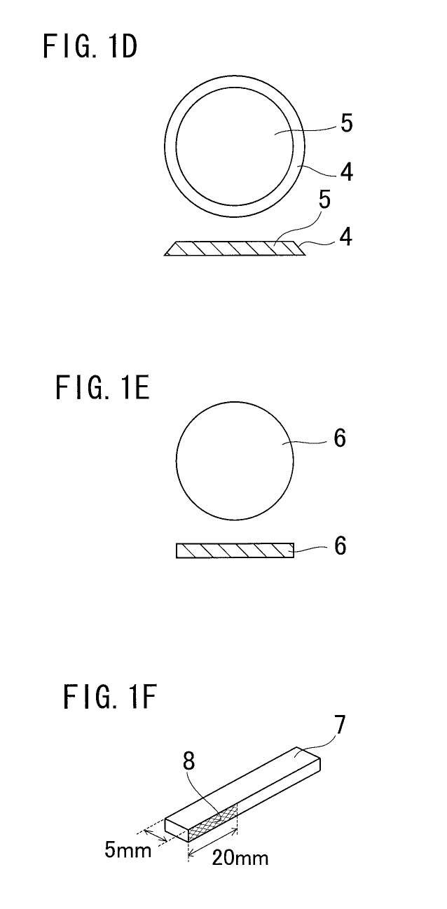

In example 1, the GaN substrate was manufactured, having a tensile stress part in the outer peripheral part of the substrate. The manufacturing step of the GaN substrate and the cleavage of the obtained GaN substrate according to the example 1 will be described by using FIG. 1.

First, a disc-shaped GaN freestanding substrate (seed crystal substrate) 1 having diameter of 60 mm and thickness of 400 μm was prepared, with c-plane (Ga plane) as the main surface (growth plane) (FIG. 1A). It was confirmed by the photoelastic measurement, that a stress distribution of the seed crystal substrate 1 was approximately uniform. Note that in each figure of FIG. 1A to FIG. 1E, an upper part is a plan view, a lower part is a sectional view, and FIG. 1F is a perspective view of the GaN substrate cleaved in a state of bars.

Next, an annular high purity carbon mask 2 having a circular opening with diameter of 55 mm was overlapped on the seed crystal substrate 1 (FIG. 1B), which was then set in the growth furnace of the HVPE apparatus in a state of being overlapped, and homoepitaxial growth of the GaN was carried out, with the c-plane as the growth surface. GaCl gas and NH₃ gas were used as raw materials for the GaN growth. The GaCl gas was generated by the reaction between Ga melt set in the upstream region of the growth furnace and the HCl gas. The partial pressure of the GaCl gas and the NH₃ gas was set to 0.8 kP and 5 kPa respectively. Mixed gas of H₂ and N₂ was used as carrier gas. Further, oxygen gas of 5 Pa was added and supplied into the growth furnace. The pressure in the growth furnace was the atmospheric pressure, and the growth temperature was set to 1060° C. At this time, the growth rate was about 120μm/h. GaN layer 3 of 600 μm was obtained by the growth of 5 hours (FIG. 1C).

Inclined growth planes 4 formed of {10-11} planes and {11-22} planes were formed on the outer peripheral part of the GaN layer 3 (part of about 350 μm inward from the outer edge in a radius direction). As a result of SIMS analysis, it was confirmed that the oxygen concentration of the c-plane growth part which is grown inside of the inclined growth planes 4 of the GaN layer 3 shows a detection lower limit (2×10¹⁶ cm⁻³) or less, and the oxygen concentration of the inclined growth part which is grown on the inclined growth planes 4 shows 1×10¹⁹ cm⁻³. Therefore, it was found that the oxygen concentration is largely different between the c-plane growth part and the inclined growth part.

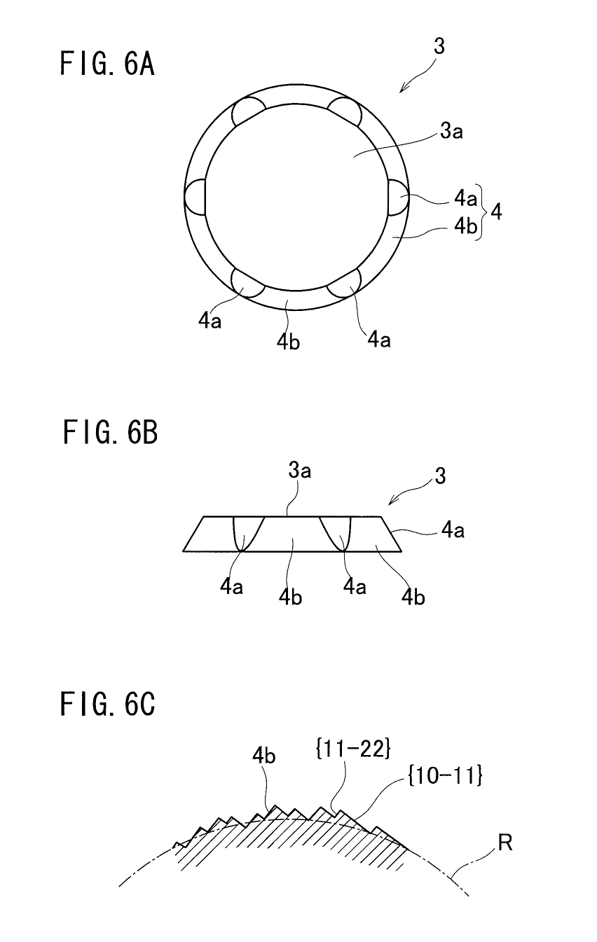

Details of the GaN layer 3 in as-grown state will be further described by using FIG. 6A to FIG. 6C. FIG. 6A is a plan view (upper side view) of the GaN layer 3 in the as-grown state, FIG. 6B is a side view of the GaN layer 3, and FIG. 6C is an expanded sectional view of a conical surface part 4b, being a part of the inclined growth planes 4 of the GaN layer 3.

As shown in FIG. 6A and FIG. 6B, the GaN layer 3 is formed into a frustconical shape as a whole. Upper surface 3a of the GaN layer 3 is formed into the c-plane, and the inclined growth planes 4, being a side face of the GaN layer 3, are formed into flat surface parts 4a and the conical surface parts 4b. The flat surface parts 4a are {10-11} planes, and appear at six places, every other 60 degrees, along the outer periphery of the frustconical-shaped GaN layer 3. The conical surface part 4b between flat surface parts 4a and 4a seems to have a conical surface by the naked eye. However, when the conical surface part 4b is observed in a state of being expanded under a microscope, as shown in FIG. 6C, the {10-11} planes and the {11-22} planes are formed into rugged surfaces in a state of being finely alternately arranged. Note that chain line in FIG. 6C shows contour R of the sectional face of the conical surface regarded as a smooth surface by the naked eye observation.

After the GaN growth is ended, the rear surface side of the substrate (the side of the seed crystal substrate 1) is subjected to grinding by 500 μm and the seed crystal substrate 1 is completely removed, then mirror surface polishing was performed. Further, grinding and polishing are also applied to the front surface side of the substrate (the side of the GaN layer 3), to thereby obtain a GaN substrate 5 with diameter of 55 mm and thickness of 400 μm and having an inclined growth part (FIG. 1D). When the photoelastic measurement was performed again to the GaN substrate 5, it was confirmed that a concentric stripe pattern was observed in the outer peripheral part within about 3 mm from the edge (outer edge) of the GaN substrate 5, and the tensile stress (called “outer peripheral tensile stress”) was generated in the outer peripheral part.

Further, the outer peripheral part including the inclined growth part of the GaN substrate 5 was subjected to grinding and processed to have a diameter of 2 inches (50.8 mm), to thereby obtain a disc-shaped GaN substrate 6 with diameter of 2 inches (FIG. 1E). Even in a case of the GaN substrate 6, wherein the outer peripheral part including the inclined growth part was subjected to grinding, when the photoelastic measurement was performed thereto, it was found that the outer peripheral tensile stress of about 50 MPa was remained. Although a high oxygen concentration region (inclined growth part), being a cause of generating the outer peripheral tensile stress, was completely removed, the tensile stress remained. The reason therefore is estimated as follows: as a result of advancing the crystal growth under an influence of the tensile stress of the outer peripheral part, variation occurs in a distribution of defects of the c-plane growth part of the center side, and as a result, variation is generated in a stress distribution.

The GaN substrate 6 obtained by the aforementioned process was set in the MOVPE apparatus, and epitaxial layers with LD (laser diode) structure were grown on the GaN substrate 6. As raw materials, TMG (trimethyl gallium), TMA (trimethyl aluminium), TMI (trimethyl indium), and NH₃ were used. As the epitaxial layers with LD structure, n-type AlGaN clad layer, an active layer with a multiple quantum well structure (MQW) of GaN barrier layer/InGaN well layer, p-type AlGaN clad layer, and p-type GaN contact layer were sequentially grown on the GaN substrate 6. Thereafter, the rear surface of the GaN substrate 6 side of the epitaxial substrate was subjected to grinding until an overall thickness was 200 μm.

Scribe line with length of 1 mm along the m-plane was added to the edge part of the rear surface side (GaN substrate 6 side) of the obtained epitaxial substrate, by using a diamond scribe apparatus. Subsequently, both sides of the scribe line were sandwiched by a flat type tweezers, and an extremely light force was added thereto by scribing so as to open a cut (slit), then the cleavage was easily completed.

In the same way, the GaN substrate 6 with diameter of 2 inches was cleaved into bars 7, each having width of 5 mm (FIG. 1F), and density of the macro-steps generated in a region (net region in the figure) of the cleavage plane 8, within 20 mm from the scribed edge part was examined by using a differential interference microscope. Namely, the macro-steps generated in the cleavage plane 8 of the aforementioned region were counted under the differential interference microscope, to thereby obtain “density of macro-steps” by dividing the count number by observed width 20 mm.

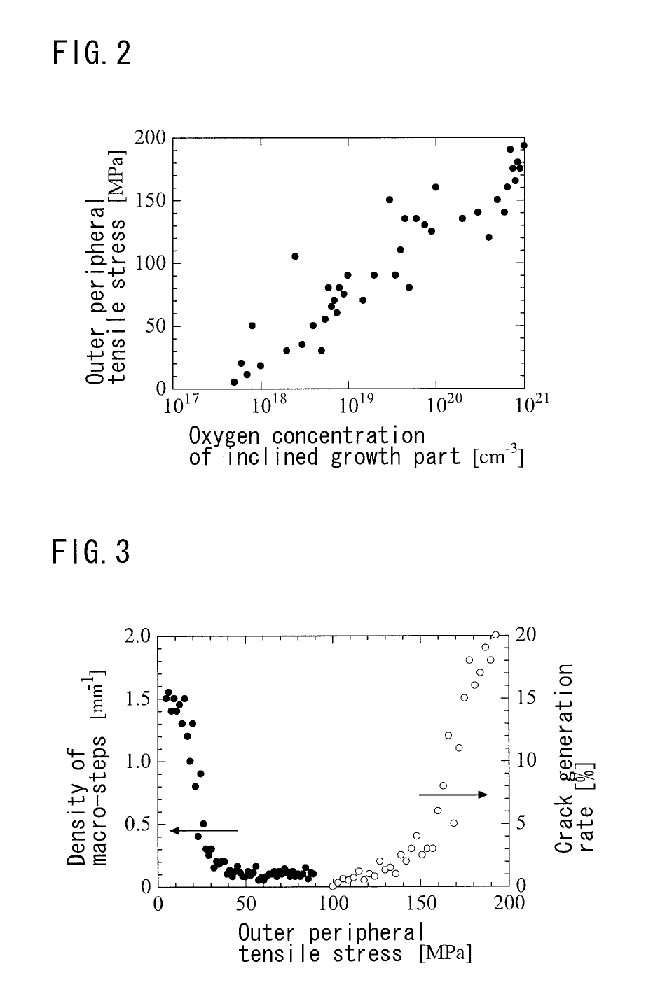

The same measurement of the density of macro-steps was performed to various GaN substrates 6 manufactured by varying the oxygen concentration of the inclined growth part of the GaN layer 3, by varying an oxygen gas partial pressure in the atmosphere during growth of the GaN layer 3. The photoelastic method was used for measuring the outer peripheral stress of the GaN substrate 6, and a value at a position of 1 mm from the edge of the GaN substrate 6 was measured. The correlation between the outer peripheral tensile stress and the oxygen concentration of the inclined growth part is shown in FIG. 2. As shown in FIG. 2, tendency of increasing the outer peripheral tensile stress was observed, in accordance with an increase of the oxygen concentration of the inclined growth part.

Further, a measurement result of the relation between the density of macro-steps in the cleavage plane and the outer peripheral tensile stress is shown in FIG. 3. It was found that a great macro-step inhibiting effect was obtained at 30 MPa or more of the outer peripheral tensile stress, and further remarkable macro-step inhibiting effect was obtained at 50 MPa or more. Moreover, as shown in FIG. 3, it was found that when the outer peripheral tensile stress exceeded 120 MPa, frequency (called “crack generation rate”) of breakages of the substrates into irregular shapes is increased during MOVPE growth and after MOVPE growth or during subsequent grinding processing, and when the outer peripheral tensile stress exceeded 150 MPa, the crack generation rate was rapidly increased. From the above-described result, it was found that excellent result was obtained by setting the outer peripheral stress to 30 MPa or more and 150 MPa or less, and further preferable effect was obtained by setting it to 50 MPa or more and 120 MPa or less.

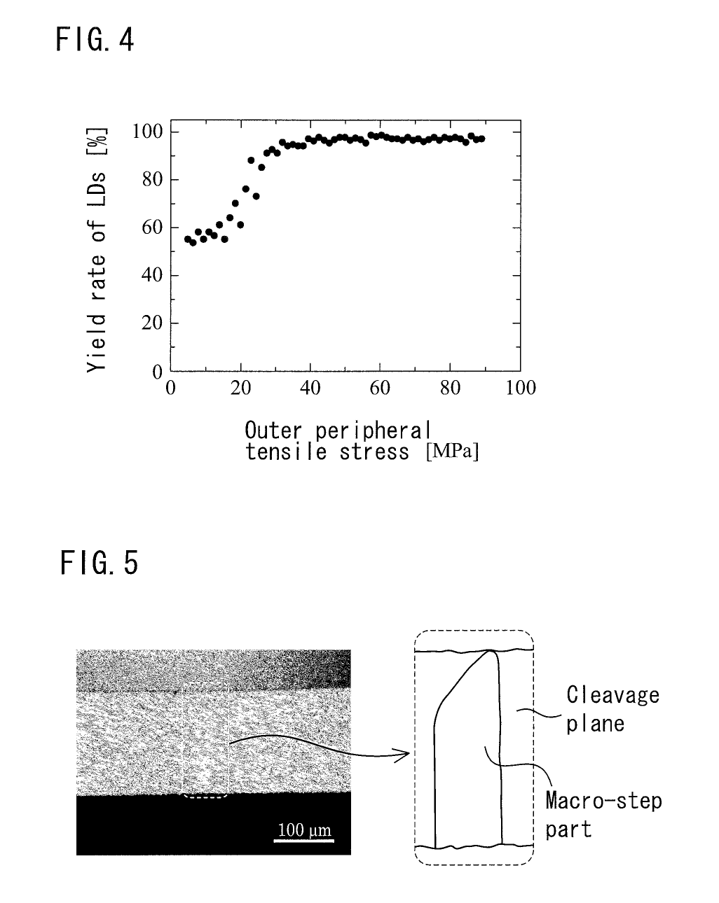

Further, regarding the GaN substrate 6 having outer peripheral tensile stress of less than 120 MPa with small crack generation rate, LDs were actually manufactured from a part whose density of macro-steps was measured, and the yield rate of the LDs was evaluated. The yield rate of the LDs was evaluated in such a manner that the LD whose threshold current value was higher than a normal value by 20% or more was regarded as a defective product. The result thereof is shown in FIG. 4. It was found that when the magnitude of the outer peripheral tensile stress was about 30 MPa or more, extremely excellent yield rate could be obtained.

### Example 2

First, the GaN substrate 6 was manufactured in the same way as the example 1. However, an oxygen supply amount during HVPE growth was adjusted, so that the oxygen concentration of the inclined growth part of the GaN layer 3 was 5×10²⁰ cm⁻³. Further, a grinding amount of the outer periphery of the GaN substrate 5 having the inclined growth part was increased, so that the diameter of the GaN substrate 6 was 45 mm. It was confirmed by the photoelastic measurement, that the outer peripheral tensile stress of 80 MPa was remained on the GaN substrate 6 of the example 2, after outer peripheral grinding was applied thereto.

The epitaxial layers with LD structure similar to the example 1 were grown on the GaN substrate 6 by the MOVPE method, then rear surface grinding was applied thereto to process the thickness to 200 μm, and thereafter the GaN substrate was cleaved to examine the density of macro-steps in the cleavage plane. Then, an extremely excellent value of 0.08/mm was obtained. At this time, the yield rate of the LDs evaluated in the same way as the example 1 was about 97% and was extremely excellent.

### COMPARATIVE EXAMPLE

In a comparative example, the cleavage property was examined, by using the GaN freestanding substrate with uniform stress distribution in the main surface (c-plane). First, the GaN freestanding substrate (seed crystal substrate) with diameter of 2 inches and thickness of 400 μm was prepared, with c-plane (Ga plane) similar to the example 1 set as the main surface. It was confirmed by the photoelastic measurement, that the stress distribution of the seed crystal substrate was approximately uniform.

Next, the seed crystal substrate of the GaN was set in the MOVPE apparatus, and in the same way as the example 1, the epitaxial layers with LD structure were grown. Thereafter, the grinding processing was applied to the rear surface until the overall thickness was 200 μm.

The scribe line with length of 1 mm along the m-plane was added to the edge part of the obtained epitaxial substrate, by using the diamond scribe apparatus. Both sides of the scribe line were sandwiched by a flat type tweezers, then a force was added thereto by scribing so as to open a cut, and the LD epitaxial substrate was cleaved. A stronger force was required than forces of examples 1, 2. When the density of macro-steps in the cleavage plane was examined in the same way as the example 1, high density of about 1.5/mm was obtained. Further, the yield rate of the LDs evaluated in the same way as the example 1 was about 55% and was extremely low.

### Example 3

In the example 3, the GaN freestanding substrate (seed crystal substrate) 1 with diameter of 6 inches (152.4 mm) and an annular high purity carbon mask 2 having a circular opening with diameter of 147.4 mm were used to carry out the growth of the GaN layer 3 of 1200 μm. In addition, the GaN substrate 5 with thickness of 1000 μm, with a bottom part having diameter of 147.4 mm, and having the inclined growth part was obtained by the manufacturing method similar to the example 1.

Note that the seed crystal substrate 1 with diameter of 6 inches is the substrate obtained by forming the GaN thin film and vapor-depositing a Ti layer on the sapphire substrate having diameter of 6 inches, and by applying heat treatment thereto, forming a void structure in the GaN thin film, then making GaN grown thick thereon by the HVPE method, and separating the sapphire substrate from the void structure part.

Even in the GaN substrate 5 of the example 3, in the same way as the example 1, it was confirmed that the concentric stripe pattern was observed in the outer peripheral part within about 3 mm from the edge of the GaN substrate 5, and the outer peripheral tensile stress was generated.

The outer peripheral part including the inclined growth part of the GaN substrate 5 was subjected to grinding, to thereby obtain a GaN substrate 6 with diameter of 143 mm. When the photoelastic measurement was performed to the GaN substrate 6, it was found that the outer peripheral tensile stress of about 50 MPa was remained.

The epitaxial layers with LD structure similar to the example 1 was grown on the GaN substrate 6 of the example 3 by the MOVPE method, then rear surface grinding was applied thereto to process the thickness to 200 μm, and the GaN substrate 6 was cleaved to examine density of macro-steps in the cleavage plane. Then, an excellent value of 0.1/mm was obtained. Further, the yield rate of the LDs evaluated in the same way as the example 1 was about 96% which was an excellent value.

### Example 4

The GaN substrate 6 with diameter of 2 inches and thickness of 400 μm was obtained by grinding the outer peripheral part including the inclined growth part, by the manufacturing step similar to that of the example 1, excluding a point that the GaN freestanding substrate (see crystal substrate) 1 was used, with the inclined surface inclined by 10 degrees from the c-plane, as the main surface. The growth plane of the GaN substrate 6 of the example 4 was formed into an inclined surface inclined by 10 degrees from the c-plane. When the photoelastic measurement was performed to the GaN substrate 6, the outer peripheral tensile stress of about 50 MPa was remained.

The epitaxial layers with LD structure similar to the example 1 were grown on the GaN substrate 6 of the example 4 by the MOVPE method, then rear surface grinding was applied thereto to process the thickness to 200 μm, and thereafter the GaN substrate was cleaved to examine the density of macro-steps in the cleavage plane. Then, it was found that the density of macro-steps in the cleavage plane was 0.09/mm and was an excellent value. Further, the yield rate of the LDs evaluated in the same way as the example 1 was about 98% which was an excellent value.

In the above-described examples, a case of manufacturing the GaN substrate is described. However, the present invention can be suitably used in manufacturing the substrate made of other group III nitride semiconductor such as AlN and AlGaN, in addition to GaN. Further, the present invention can be similarly applied to a high temperature high pressure method, liquid phase growth such as Na flux method, and an ammonothermal method, in addition to the HVPE method.

What is claimed is:

1. A Group III nitride semiconductor substrate with diameter of 25 mm or more and thickness of 250 μm or more, wherein in at least an outer edge side part of an outer edge part within 5 mm from an outer edge of the group III nitride semiconductor substrate, stress within a main surface of the group III nitride semiconductor substrate works as a tensile stress, with the tensile stress becoming relatively greater compared to that of a center side part from the outer edge side part of the group III nitride semiconductor substrate.

2. The group III nitride semiconductor substrate according to claim 1, wherein magnitude of the tensile stress of the outer edge side part is 30 MPa or more and 150 MPa or less.

3. The group III nitride semiconductor substrate according to claim 1, wherein the main surface is c-plane or an inclined surface inclined from the C-plane.

4. The group III nitride semiconductor substrate according to claim 2, wherein the main surface is c-plane or an inclined surface inclined from the c-plane.

5. The group III nitride semiconductor substrate according to claim 1, wherein the group III nitride semiconductor substrate is a GaN substrate.

6. The group III nitride semiconductor substrate according to claim 2, wherein the group III nitride semiconductor substrate is a GaN substrate.

7. The group III nitride semiconductor substrate according to claim 3, wherein the inclined surface is a surface inclined from the c-plane in an angle range of 10°.

8. The group III nitride semiconductor substrate according to claim 1, wherein thickness of the group III nitride semiconductor substrate is 1 mm or less.

9. A manufacturing method of a group III nitride semiconductor substrate, comprising the steps of:
preparing a seed crystal substrate; and
supplying a raw material to the seed crystal substrate and crystal-growing thereon a group III nitride semiconductor layer,
wherein in the step of crystal-growing the group III nitride semiconductor layer on the seed crystal substrate, the group III nitride semiconductor layer crystal-grows on an outer peripheral part thereof while growth planes are formed so as to be inclined to a main surface of the seed crystal substrate at an angle larger than 0° and smaller than 90°, with a doping concentration of the group III nitride semiconductor layer of the outer peripheral part having the inclined growth planes, set to be higher than the doping concentration of the group III nitride semiconductor layer of a center side from the outer peripheral part.

10. The manufacturing method of the group III nitride semiconductor substrate according to claim 9, wherein Hydride Vapor Phase Epitaxy is used in crystal growth of the group III nitride semiconductor layer, and the crystal growth is carried out in an atmosphere where oxygen gas or oxygen compound gas exits.

11. The manufacturing method of the group III nitride semiconductor substrate according to claim 10, wherein the oxygen gas or the oxygen compound gas is supplied from outside of a growth furnace in which the crystal growth is carried out, or is generated by a reaction between a quartz member constituting the growth furnace and atmosphere gas in the growth furnace.

12. The manufacturing method of the group III nitride semiconductor substrate according to claim 10, wherein oxygen concentration added to the group III nitride semiconductor substrate of the outer peripheral part having the inclined growth planes, is 1×10¹⁸ cm⁻³ or more and 5×10²⁰ cm⁻³ or less.

13. The manufacturing method of the group III nitride semiconductor substrate according to claim 9, comprising the step of grinding the outer peripheral part of the group III nitride semiconductor layer, after the step of crystal-growing the group III nitride semiconductor layer.

14. The manufacturing method of the group III nitride semiconductor substrate according to claim 10, comprising the step of grinding the outer peripheral part of the group III nitride semiconductor layer, after the step of crystal-growing the group III nitride semiconductor layer.

15. The manufacturing method of the group III nitride semiconductor substrate according to claim 9, wherein the group III nitride semiconductor layer is a GaN layer.

16. The manufacturing method of the group III nitride semiconductor substrate according to claim 10, wherein the group III nitride semiconductor layer is a GaN layer.

17. The manufacturing method of the group III nitride semiconductor substrate according to claim 9, wherein in the step of crystal-growing the group III nitride semiconductor layer, the outer peripheral part of the surface of the seed crystal substrate is covered with a mask, and the group III nitride semiconductor layer is crystal-grown on the seed crystal substrate inside of the mask.

18. The manufacturing method of the group III nitride semiconductor substrate according to claim 9, wherein a main surface of the seed crystal substrate is a c-plane or an inclined surface inclined from the c-plane.

19. The manufacturing method of the group III nitride semiconductor substrate according to claim 10, wherein the main surface of the seed crystal substrate is a c-plane or an inclined surface inclined from the c-plane.

20. The manufacturing method of the group III nitride semiconductor substrate according to claim 19, wherein the inclined growth planes are {10-11} planes and {11-22} planes.
